(19) United States
(12) Patent Application Publication
(10) Pub. No.: US 2026/0231836 A1
(43) Pub. Date: Aug. 6, 2026

(54) FINE-PITCH INTEGRATION WITHOUT INTERPOSER AND TSV

(71) Applicant: INTERNATIONAL BUSINESS MACHINES CORPORATION, ARMONK, NY (US)

(72) Inventors: Qianwen Chen, Fort Collins, NY (US); Nicholas Alexander Polomoff, Hopewell Junction, NY (US); Michael P. Belyansky, Halfmoon, NY (US); Joshua Mark Rubin, Albany, NY (US); Katsuyuki Sakuma, Fishkill, NY (US); John Knickerbocker, Monroe, NY (US); Roy R. Yu, Poughkeepsie, NY (US)

(21) Appl. No.: 19/045,517

(22) Filed: Feb. 4, 2025

(51) Int. Cl. H10W 90/00; H10W 70/05; H10W 70/60; H10W 70/65; H10B 80/00; H10W 70/695; H10W 74/01; H10W 80/00

(52) U.S. Cl. CPC H10W 90/401; H10W 70/05; H10W 70/611; H10W 70/65; H10B 80/00; H10W 70/695; H10W 74/01; H10W 80/312; H10W 80/327; H10W 90/00; H10W 90/794

(57) ABSTRACT

A semiconductor device includes a substrate, an organic buffer layer over the substrate, a redistribution layer (RDL) over the organic buffer layer, and one or more semiconductor dies over the RDL. The one or more semiconductor dies are face-to-face hybrid bonded to the RDL.

### BACKGROUND

### Technical Field

The present disclosure generally relates to semiconductors, and more particularly, to semiconductors with fine-pitch integration without interposer and TSV structure, and methods of creation thereof.

### Description of the Related Art

The continuous miniaturization of transistors and their increasing density on chips are hallmark innovations in the semiconductor industry, closely following Moore’s Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a substrate, an organic buffer layer over the substrate, a redistribution layer (RDL) over the organic buffer layer, and one or more semiconductor dies over the RDL. The one or more semiconductor dies are face-to-face hybrid bonded to the RDL.

In one embodiment, the one or more semiconductor dies are encapsulated.

In one embodiment, the substrate includes a plurality of interconnections and a plurality of pads.

In one embodiment, the organic buffer layer includes a plurality of interconnections and a plurality of pads.

In one embodiment, the semiconductor device includes back-to-back connections between the RDL and the organic buffer layer.

In one embodiment, the organic buffer layer is face-to-face joined to the substrate.

In one embodiment, the RDL includes a plurality of interconnections, a plurality of pads; and a dielectric layer.

In one embodiment, the dielectric is made of at least one of: SiO2, SiN and SiCN.

In one embodiment, the semiconductor device includes a logic device, a passive device, and one or more high bandwidth memory.

According to an embodiment, a method for fabrication of a semiconductor device includes forming a substrate, forming an organic buffer layer over the substrate, forming a redistribution layer (RDL) over the organic buffer layer, forming one or more semiconductor dies over the RDL, and bonding the one or more semiconductor dies to the RDL, wherein the bonding is a hybrid bonding.

In one embodiment, the method includes encapsulating the one or more semiconductor dies.

In one embodiment, the method includes forming a plurality of interconnections; and forming a plurality of pads.

In one embodiment, the method includes forming a plurality of interconnections; and forming a plurality of pads.

In one embodiment, the method includes forming back-to-back connections between the RDL and the organic buffer layer.

In one embodiment, the method includes face-to-face joining the organic buffer layer to the substrate.

In one embodiment, the method includes forming a plurality of interconnections; forming a plurality of pads, and forming a dielectric layer.

In one embodiment, the dielectric is made of at least one of: SiO2, SiN and SiCN.

In one embodiment, the method includes forming a logic device, forming a passive device, and forming one or more high bandwidth memory.

According to an embodiment, a semiconductor device includes a buffer layer, a redistribution layer (RDL) over the buffer layer, and one or more semiconductor dies over the RDL. Each of the buffer layer and the RDL includes at least: one or more interconnects and one or more pads, and wherein the RDL and the buffer layer are connected via back-to-back connections.

In one embodiment, the semiconductor device includes a substrate comprising one or more interconnections and one or more pads, and one or more semiconductor dies over the RDL.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a conventional packaged semiconductor.

FIG. 2A illustrates a semiconductor device, in accordance with some embodiments.

FIG. 2B illustrates a face-to-face bind interface in the semiconductor device, in accordance with some embodiments.

FIG. 2C illustrates a back-to-back bind interface in the semiconductor device, in accordance with some embodiments.

FIG. 3 illustrates a semiconductor device after preparing the substrate, in accordance with some embodiments.

FIG. 4 illustrates a semiconductor device after the formation of interconnects and pads, in accordance with some embodiments.

FIG. 5 illustrates a semiconductor device after the formation of semiconductor dies, in accordance with some embodiments.

FIG. 6 illustrates a semiconductor device after the encapsulation of the dies, in accordance with some embodiments.

FIG. 7 illustrates a semiconductor device after the backside grinding, in accordance with some embodiments.

FIG. 8 illustrates a semiconductor device after the attachment of the second silicon wafer, in accordance with some embodiments.

FIG. 9 illustrates a semiconductor device after the wafer is flipped, in accordance with some embodiments.

FIG. 10 illustrates a semiconductor device after the release of the first silicon wafer, in accordance with some embodiments.

FIG. 11 illustrates a semiconductor device after the build-up organic buffer layer, in accordance with some embodiments.

FIG. 12 illustrates a semiconductor device after the dicing the semiconductor device, in accordance with some embodiments.

FIG. 13 illustrates a semiconductor device after the bonding the dies to the substrate, in accordance with some embodiments.

FIG. 14 illustrates a semiconductor device after the release of the second silicon wafer, in accordance with some embodiments.

FIG. 15 illustrates a semiconductor device after the assembling of additional devices, in accordance with some embodiments.

FIGS. 16A-16B illustrate a semiconductor device with different bonding, in accordance with some embodiments.

FIG. 17 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

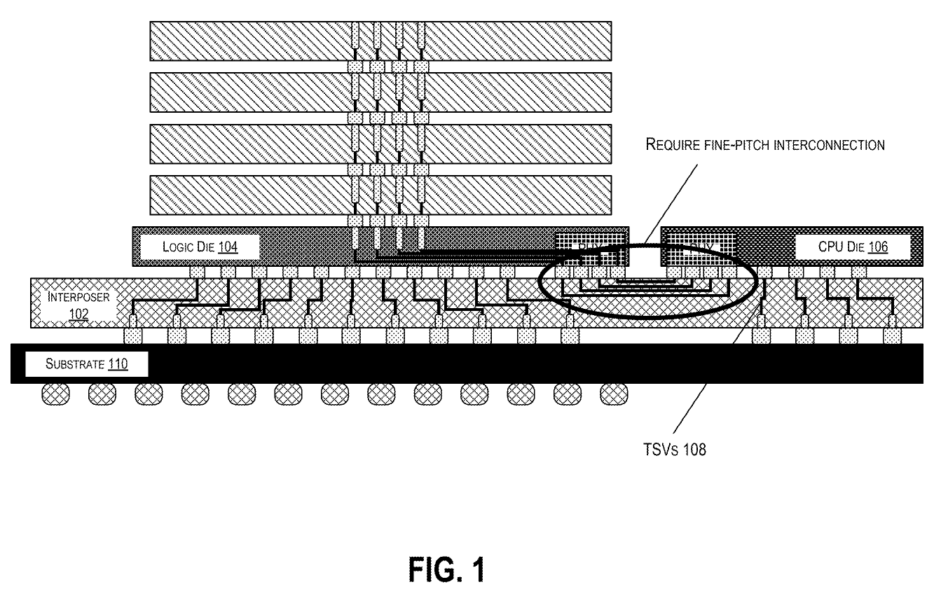

Interposers equipped with through-silicon vias (TSVs) have become a fundamental component in modern 3D semiconductor packaging, enabling fine-pitch interconnections between multiple dies stacked vertically. FIG. 1 illustrates a conventional semiconductor packaging with interposer and TSVs. The interposer 102 serves as an intermediary layer that facilitates the routing of electrical signals between dies, such as logic die 104, and CPU die 106, while TSVs 108 provide vertical pathways that traverse the substrate 110, allowing for high-density and high-speed communication across stacked layers. This architecture is pivotal in applications requiring substantial bandwidth and reduced latency, such as high-performance computing, advanced graphics processing units (GPUs), and artificial intelligence (AI) accelerators.

However, the fabrication of high-aspect-ratio TSVs presents significant challenges that impact both the efficiency and cost-effectiveness of 3D packaging solutions. High-aspect-ratio TSVs, which have a much greater depth compared to their width, are inherently difficult to manufacture due to the precision required in etching deep, narrow vias through the silicon substrate. The processes involved, such as deep reactive ion etching (DRIE) and subsequent metallization, are not only time-consuming but also demand advanced fabrication techniques and stringent quality control measures to ensure reliability and performance. Additionally, the complexity of integrating TSVs with interposers increases the overall manufacturing complexity, leading to higher production costs and longer lead times. These factors collectively limit the scalability and economic viability of TSV-based 3D integration, particularly for mass-market applications where cost sensitivity is paramount.

Addressing these challenges, the present disclosure introduces a novel fine-pitch 3D integration structure that eliminates the need for traditional interposers and TSVs. This innovative approach leverages advanced interconnection technologies and alternative vertical integration methods to achieve fine-pitch interconnections without relying on high-aspect-ratio TSVs. By removing the interposer layer, the proposed structure reduces the number of fabrications steps, simplifies the overall packaging process, and reduces (e.g., minimizes) the associated manufacturing costs. The elimination of TSVs further streamlines the integration process, as it removes the need for intricate etching and metallization procedures required for high-aspect-ratio vias.

The disclosed fine-pitch 3D integration structure employs alternative interconnect mechanisms, such as micro-bumps or advanced bonding techniques, which facilitate dense and reliable connections between stacked dies. These methods offer comparable electrical performance to TSVs while significantly reducing fabrication time and costs. Moreover, the simplified architecture enhances thermal management and mechanical stability, as the absence of an interposer and TSVs decreases thermal resistance and potential points of mechanical failure. This results in a more robust and thermally efficient package, capable of supporting high-performance applications with improved reliability and reduced thermal challenges.

Accordingly, the teachings herein provide methods and systems of semiconductor devices with fine-pith integration without interposer and TSV. The techniques described herein may be implemented in a number of ways. Example implementations are provided below with reference to the following figures.

### Example Semiconductor Device with Fine-Pitch Integration Without Interposer and TSV Structure

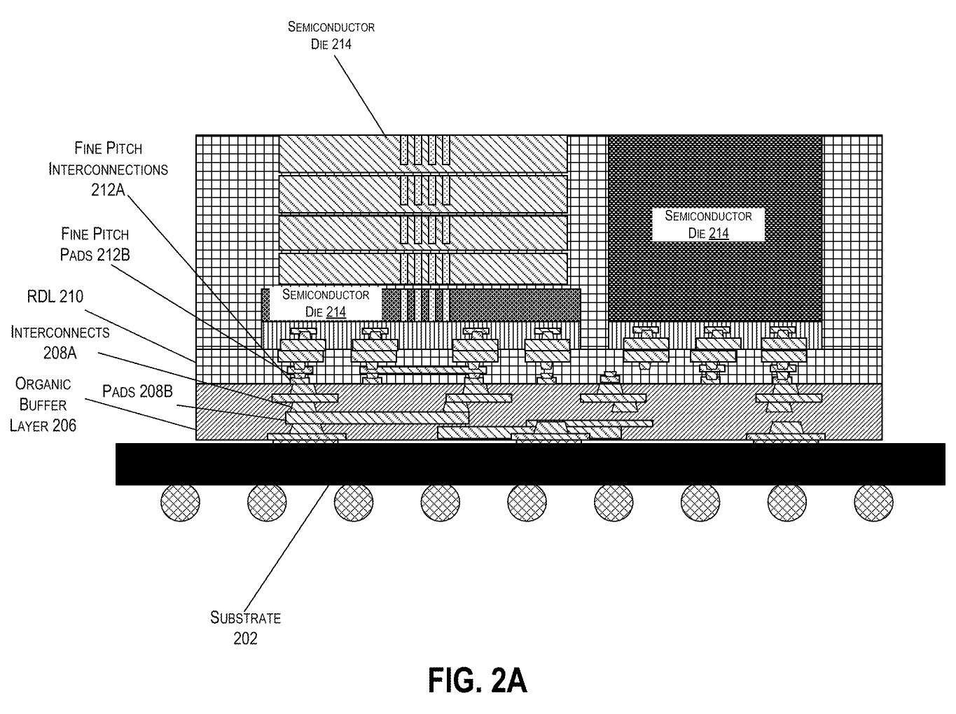

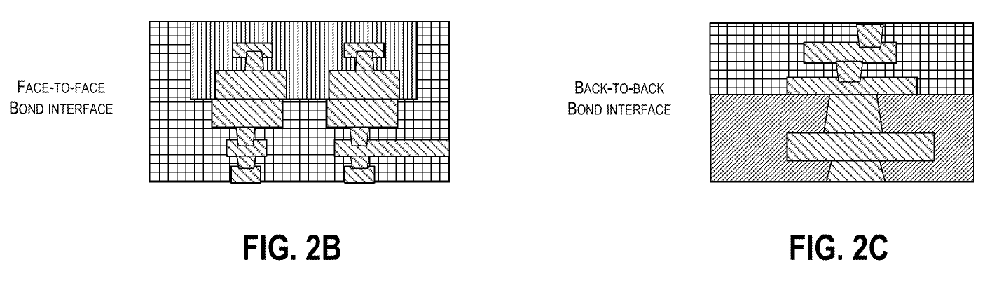

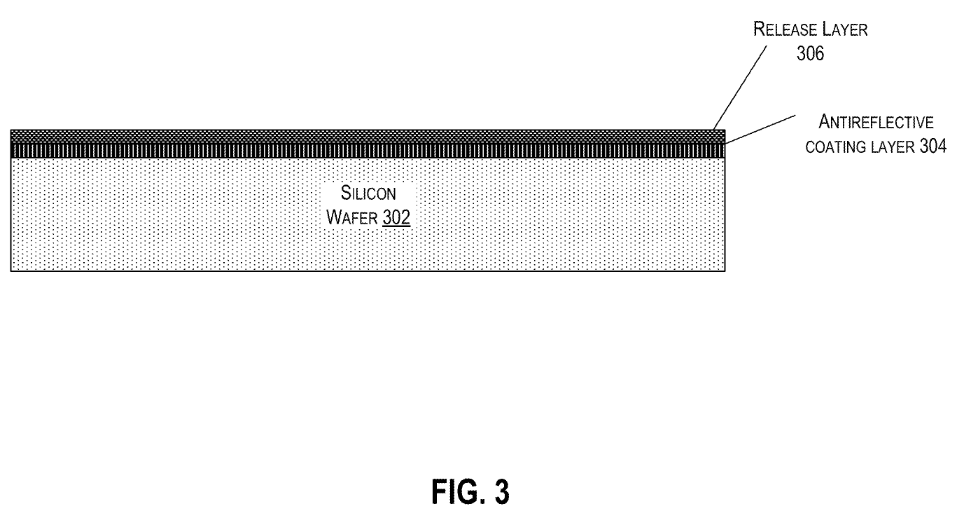

Reference now is made to FIGS. 2A-2C, which is a simplified cross-section view of a of the semiconductor device. FIG. 2A illustrates a semiconductor device, in accordance with some embodiments. In some embodiments, the semiconductor device includes a substrate 202 that serves as the foundational platform for the entire assembly. The substrate 202 provides mechanical support and facilitates electrical connections throughout the device. It is engineered to include a plurality of interconnections and a plurality of pads, which are essential for establishing robust and reliable electrical pathways. The plurality of interconnections within the substrate 202 enable the routing of electrical signals between various components, ensuring seamless communication and functionality across the semiconductor device. The plurality of pads on the substrate 202 acts as connection points for interfacing with external circuits or other internal layers, allowing the device to integrate effectively into larger electronic systems.

In some embodiments, an organic buffer layer 206 is positioned over the substrate 202 . This organic buffer layer 206 facilitates managing mechanical and thermal stresses that arise due to differences in material properties between the substrate and subsequent layers. The organic buffer layer 206 includes a plurality of interconnections 208A and a plurality of pads 208B , which facilitate additional electrical connections and signal routing within the device. By incorporating these interconnections and pads, the organic buffer layer 206 ensures that electrical signals can traverse multiple layers of the semiconductor device without degradation or interference. Furthermore, the organic nature of the buffer layer provides flexibility and resilience, allowing it to absorb and dissipate mechanical stresses, thereby enhancing the overall durability and reliability of the semiconductor package. The buffer layer's ability to accommodate thermal expansion and contraction reduces (e.g., minimizes) the risk of delamination or cracking, ensuring sustained performance under varying operating conditions.

In some embodiments, the organic buffer layer 206 is face-to-face joined to the substrate 202 . This face-to-face joining establishes a direct and secure interface between the substrate and the buffer layer, promoting effective mechanical bonding and electrical connectivity. The alignment and bonding precision can maintain the integrity of the interconnections and pads within both the substrate and the buffer layer. The joining process ensures that electrical signals can pass seamlessly from the substrate to the buffer layer and vice versa, without any loss or distortion. Additionally, the face-to-face joining enhances the thermal management capabilities of the device by providing a continuous pathway for heat dissipation from the substrate through the buffer layer. This integration is essential for maintaining optimal operating temperatures and preventing thermal-induced failures, thereby contributing to the overall performance and longevity of the semiconductor device.

In some embodiments, the semiconductor device includes a redistribution layer, RDL 210 , positioned over the organic buffer layer 206 . The RDL 210 serves as an intermediary layer that reroutes electrical connections from the fine-pitch interconnections and pads of the buffer layer to the broader and more accessible layout required for interfacing with semiconductor dies and other components. The RDL includes a plurality of fine-pitch (nm-size) interconnections 212A and fine-pitch pads 212B with line and space (L/S) dimensions less than 3 micrometers (µm). These fine-pitch features are fabricated using advanced techniques such as copper (Cu) damascene or aluminum (Al) patterning, which allow for precise and high-density routing essential for modern semiconductor applications.

The RDL 210 can include a dielectric layer. The dielectric layer within the RDL 210 is made of materials such as silicon dioxide (SiO₂), silicon nitride (Si₃N₄), or silicon carbonitride (SiCN). These materials are selected for their electrical insulating properties, which prevent unintended electrical interactions between the interconnections and ensure reliable signal transmission. The dielectric layer also contributes to the mechanical stability of the RDL 210 , maintaining the spacing and alignment of the interconnections and pads. By providing electrical insulation and structural support, the dielectric layer enhances the overall reliability and performance of the semiconductor device, ensuring that electrical signals can traverse the RDL 210 with reduced (e.g., minimal) loss or interference.

In some embodiments, the RDL 210 establishes back-to-back connections with the organic buffer layer 206 . The back-to-back connections involve the direct linkage of interconnections and pads from the buffer layer to those on the RDL 210 , creating a continuous and efficient pathway for electrical signals. This configuration ensures that electrical signals can move seamlessly from the organic buffer layer 206 through the RDL 210 to the semiconductor dies, facilitating high-speed and high-density communication within the device. The back-to-back connections also enhance the mechanical integrity of the assembly, providing additional support and stability to the interconnections and pads. This robust connectivity is essential for maintaining consistent electrical performance and reducing the likelihood of signal degradation or loss, thereby ensuring that the semiconductor device operates reliably under various conditions.

In some embodiments, the semiconductor device includes one or more semiconductor dies 214 positioned over the RDL 210 . The one or more semiconductor dies 214 are face-to-face hybrid bonded to the RDL, establishing a direct and robust connection between the dies and the redistribution layer. Hybrid bonding involves the combination of different bonding techniques, such as direct metal-to-metal bonding and dielectric bonding, to achieve a high-density and reliable interface between the dies and the RDL. The face-to-face hybrid bonding ensures that electrical signals can be transmitted with reduced (e.g., minimal) loss and that power can be efficiently distributed across the semiconductor dies. The alignment and bonding process are critical to maintaining the integrity of the interconnections and ensuring that the semiconductor dies operate seamlessly within the integrated device.

In some embodiments, the one or more semiconductor dies 214 are encapsulated. Encapsulation involves enclosing the dies in a protective material, such as an epoxy or silicone compound, to safeguard them from environmental factors such as moisture, dust, and mechanical shocks. Encapsulation also helps in managing thermal dissipation by providing a barrier that facilitates the efficient transfer of heat from the dies to the surrounding thermal management structures, such as heat spreaders or heat sinks. By encapsulating the dies, the semiconductor device gains enhanced durability and reliability, ensuring that the dies remain protected and function optimally throughout the device’s operational lifespan.

In some embodiments, the substrate 202 includes a plurality of interconnections and a plurality of pads. These interconnections serve as pathways for electrical signals, enabling communication between active components like semiconductor dies and passive components such as resistors, capacitors, and inductors. The plurality of pads on the substrate provides standardized connection points for interfacing with external circuits, power supplies, and other semiconductor devices. This arrangement ensures that the semiconductor device can be seamlessly integrated into larger electronic systems, maintaining high levels of performance and reliability. The substrate's design is optimized to support high-density interconnections, facilitating the compact and efficient layout required for advanced semiconductor applications.

In some embodiments, the organic buffer layer 206 includes a plurality of interconnections and a plurality of pads. These interconnections and pads within the organic buffer layer replicate the patterning of the substrate, enabling additional layers of electrical connectivity and signal routing. The organic buffer layer's interconnections provide redundant pathways for electrical signals, enhancing the device's fault tolerance and reliability. The inclusion of pads within the buffer layer ensures that there are multiple points of connection for interfacing with the redistribution layer, allowing for greater flexibility in design and integration. This layered approach to interconnection ensures that the semiconductor device can handle complex signal routing requirements, supporting high-speed and high-density applications without compromising performance.

In some embodiments, the semiconductor device further includes back-to-back connections between the RDL 210 and the organic buffer layer 206 . The connections are established through precise alignment and bonding of the interconnections and pads on both layers, creating a seamless electrical pathway that facilitates efficient signal transmission. The back-to-back connections ensure that electrical signals can be routed from the substrate 202 through the organic buffer layer 206 and into the RDL 210 without any loss of signal integrity. This configuration enhances the overall performance of the semiconductor device by reducing (e.g., minimizing) signal latency and increasing (e.g., maximizing) data throughput, which are critical factors in high-performance computing and data-intensive applications.

FIG. 2B illustrates a face-to-face bind interface in the semiconductor device, in accordance with some embodiments. FIG. 2C illustrates a back-to-back bind interface in the semiconductor device, in accordance with some embodiments. In some embodiments, the organic buffer layer 206 is face-to-face joined to the substrate 202 . The face-to-face joining ensures that the interconnections and pads on the buffer layer are directly aligned with those on the substrate, enabling efficient and reliable electrical connections. The joining process involves advanced bonding techniques that ensure a strong mechanical and electrical bond between the two layers, preventing any misalignment or signal loss. The alignment can help maintaining the high-density interconnect requirements of modern semiconductor devices, allowing for seamless communication between multiple layers of interconnections and ensuring that the device can support complex and high-speed applications.

In some embodiments, the RDL 210 includes a dielectric layer made of silicon dioxide (SiO₂), silicon nitride (Si₃N₄), or silicon carbonitride (SiCN). The dielectric materials are chosen for their electrical insulating properties, which are important for preventing short circuits and ensuring the integrity of electrical signals within the RDL 210 . The dielectric layer also plays a role in managing thermal dissipation, allowing heat generated by the semiconductor dies to be effectively conducted away through the RDL 210 and into the substrate 202 or other thermal management structures. The dual functionality of electrical insulation and thermal management makes the dielectric layer an indispensable component of the RDL 210 , contributing to the overall performance and reliability of the semiconductor device.

In some embodiments, the one or more semiconductor dies 214 include a logic device, a passive device, and one or more high bandwidth memory, HBM, components. The logic device handles the computational and control functions of the semiconductor device, executing instructions and managing data flow. The passive device includes components such as resistors, capacitors, and inductors that support the electrical circuitry and signal integrity of the device. The HBM components provide fast and efficient data storage and retrieval, supporting the high-speed data processing requirements of the semiconductor device. These additional components are integrated into the substrate 202 and interconnected through the organic buffer layer 206 and RDL 210 , ensuring seamless communication and efficient performance across the entire semiconductor device.

In some embodiments, the HBM is placed and interconnected through the fine-pitch interconnections and pads of the RDL 210 . This placement allows for rapid data access and high-speed communication between the memory and the logic device, facilitating efficient data processing and reducing (e.g., minimizing) latency. The integration of high bandwidth memory within the semiconductor device enhances its overall performance, enabling it to handle demanding applications such as high-performance computing, artificial intelligence, and advanced graphics processing. The fine-pitch interconnections ensure that the high-density memory components can communicate effectively without signal interference or degradation, maintaining the integrity and reliability of data transmission within the device.

In some embodiments, HBM and GPU dies are directly connected to the package substrate using the RDL instead of a traditional silicon (Si) interposer. This approach leverages the RDL’s fine-pitch interconnections to facilitate high-density and high-speed electrical connections between the memory and processing units. By eliminating the silicon interposer, the semiconductor device reduces both manufacturing complexity and costs, making the overall packaging solution more economical. The RDL serves as an intermediary layer that redistributes the electrical connections from the densely packed I/O pads of the HBM and GPU dies to the broader and more accessible layout of the package substrate. This fine-pitch RDL, characterized by nanometer-scale interconnections and sub-3-micrometer pads, is fabricated using advanced techniques such as copper (Cu) damascene or aluminum (Al) patterning. These methods enable precise and high-density routing essential for modern high-performance applications, ensuring that the HBM and GPU can communicate efficiently without the need for an additional interposer layer.

One advantage of this RDL-based connection method is its low-cost implementation. Silicon interposers are not only expensive to produce due to their complex fabrication processes but also add significant material and assembly costs to the semiconductor package. By using an RDL, the need for a separate interposer is eliminated, thereby streamlining the manufacturing process and reducing the overall cost of the device. Additionally, the simplified package structure results in fewer fabrication steps, which further contributes to cost savings and shorter production times. Moreover, the RDL-based connection offers process compatibility with existing semiconductor manufacturing technologies. The RDL can be integrated seamlessly into standard packaging workflows, utilizing materials and processes that are already well-established in the industry. The compatibility ensures that manufacturers can adopt the RDL approach without the need for extensive changes to their production lines or significant investments in new equipment. As a result, the transition to RDL-based connections is both practical and efficient, supporting scalability and mass production.

The elimination of the silicon interposer also enhances the thermal management of the semiconductor device. The RDL provides efficient pathways for heat dissipation from the HBM and GPU dies directly to the package substrate, improving the overall thermal performance and reliability of the device. This direct connection reduces (e.g., minimizes) thermal resistance and allows for more effective cooling, which is crucial for maintaining optimal operating temperatures in high-performance applications.

### Example Acts of Semiconductor Device with Fine-Pitch Integration Without Interposer and TSV Structure

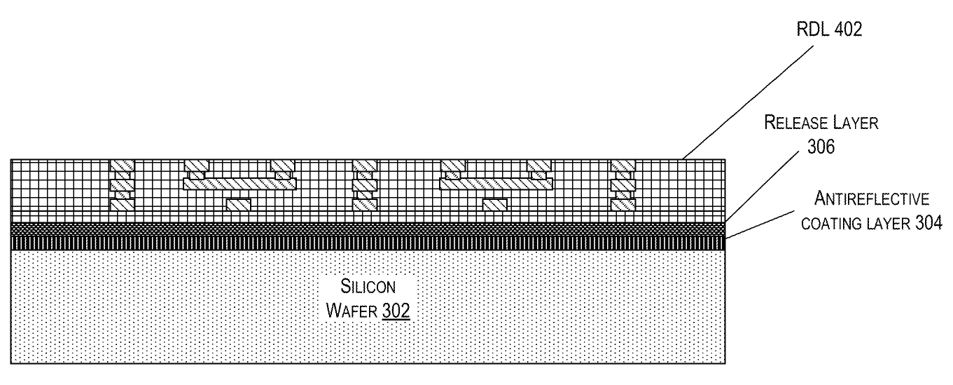

Reference now is made to FIGS. 3-15, which are simplified cross-section views of acts of fabrication of the semiconductor device. As shown in FIG. 3, in some embodiments, the semiconductor device includes a silicon wafer 302 , an antireflective coating layer 304 , and a release layer 306 . The antireflective coating layer 304 can be a thin dielectric layer, e.g., with a nanometer-size thickness, such as SiO2, SiN, SiCN. The release layer 306 can be a thin metal layer, e.g., with a nanometer-size thickness, such as Ti, Ta, TiN, TaN, Al.

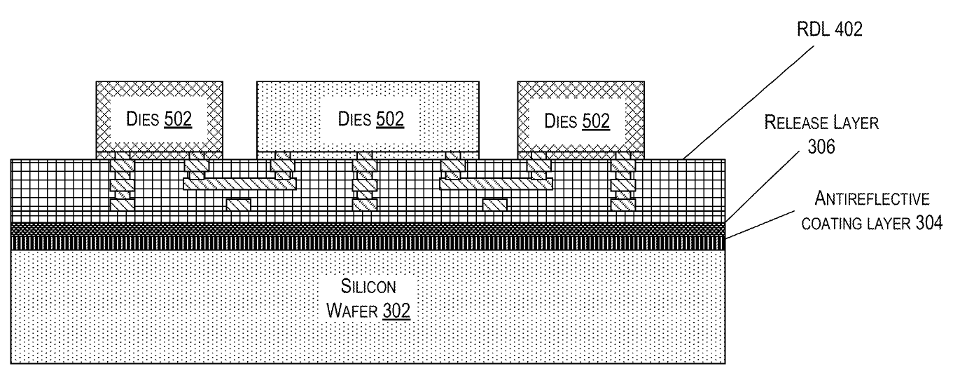

FIG. 4 illustrates a semiconductor device after the formation of interconnects and pads, in accordance with some embodiments. In some embodiments, the semiconductor device utilizes the silicon carrier as the foundational substrate for constructing highly intricate electrical connections. The process involves building up fine-pitch interconnections and pads, e.g., the RDL 402, where the interconnections have feature sizes measured in nanometers (nm) and the pads are less than three micrometers (µm) in dimension. Achieving such fine pitches is critical for enhancing the density and performance of modern semiconductor devices, enabling more compact and efficient electronic circuits. The fabrication of the fine-pitch interconnections and pads on the carrier is accomplished using Copper (Cu) Damascene processes. The Cu Damascene process is a method in semiconductor manufacturing for creating precise and reliable copper interconnects. This technique involves several key steps: first, a patterned dielectric layer is etched to form trenches and vias where the copper will be deposited. Next, a barrier layer is applied to prevent copper diffusion and ensure adhesion to the dielectric. Following this, the trenches and vias are filled with copper through electroplating, resulting in robust and low-resistance electrical pathways.

After the copper deposition, a chemical-mechanical polishing (CMP) step can be performed to remove excess copper and achieve a smooth, planar surface. This planarization helps maintaining the integrity of the fine-pitch interconnections and ensuring that subsequent layers can be accurately patterned and aligned. The Cu Damascene process allows for the creation of dense interconnects with reduced (e.g., minimal) feature sizes and enhances the overall electrical performance by reducing signal delay and power consumption. By integrating fine-pitch interconnections and pads on a silicon carrier using Cu Damascene processes, the semiconductor device achieves higher interconnect density and improved electrical characteristics.

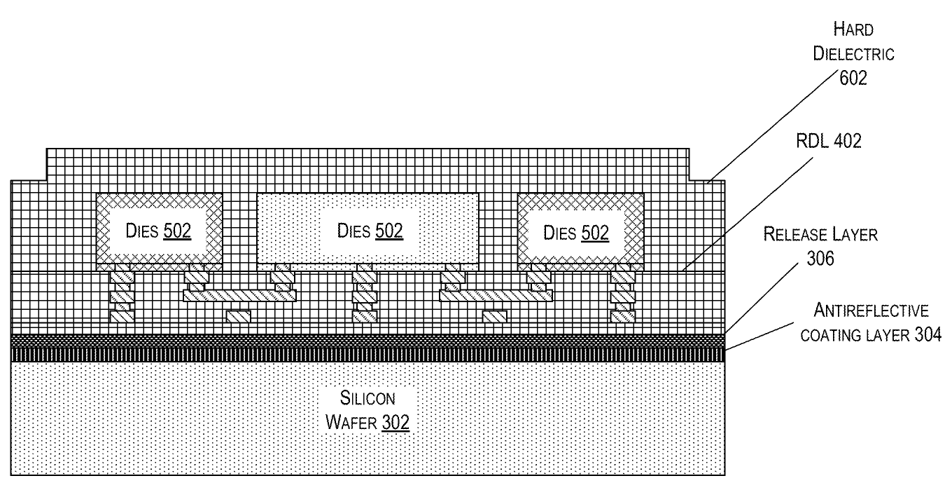

FIG. 5 illustrates a semiconductor device after the formation of semiconductor dies, in accordance with some embodiments. In some embodiments, the semiconductor device employs a C2W hybrid bonding method for die assembly on wafers. The C2W (Chip-to-Wafer) hybrid bonding technique facilitates the precise alignment and bonding of semiconductor dies directly onto the wafer substrate. This method ensures that the dies are securely attached while maintaining high alignment accuracy, which is essential for reliable electrical interconnections. The hybrid bonding process combines both metal-to-metal and dielectric bonding techniques, allowing for robust mechanical and electrical connections between the dies and the wafer.

In some embodiments, the dies 502 are electrically interconnected with the RDL 402 through the C2W hybrid bonding method. The RDL 402 features nanometer-scale interconnections and sub-3-micrometer pads, enabling high-density routing of electrical signals. This high-density interconnectivity is important for advanced semiconductor applications that demand rapid data transfer and reduced (e.g., minimal) signal latency. The RDL 402 serves as an intermediary layer that redistributes the electrical connections from the densely packed I/O pads of the dies to a more accessible layout on the wafer, ensuring efficient communication and functionality across the device. In some embodiments, both bonding dielectric interfaces can be adjusted or modified based on stress requirements to enhance the reliability of the die assembly. Materials such as tetraethyl orthosilicate (TEOS), silicon nitride (SiN), and silicon carbonitride (SiCN) are utilized with varying thicknesses to tailor the mechanical and thermal properties of the bonding interface. By selecting appropriate dielectric materials and adjusting their thicknesses, the bonding interfaces can better accommodate thermal expansion mismatches and mechanical stresses, thereby reducing the risk of delamination or peeling of the dies from the wafer substrate.

In some embodiments, additional fabrication parameters such as annealing temperature and duration are meticulously controlled to mitigate stress accumulation at the bonding interfaces. Precise control of annealing conditions ensures optimal bonding strength while preventing excessive thermal stresses that could compromise the integrity of the die assembly. By fine-tuning these parameters, the manufacturing process enhances the durability and reliability of the semiconductor device, ensuring that the dies remain securely bonded to the wafer even under varying operational conditions.

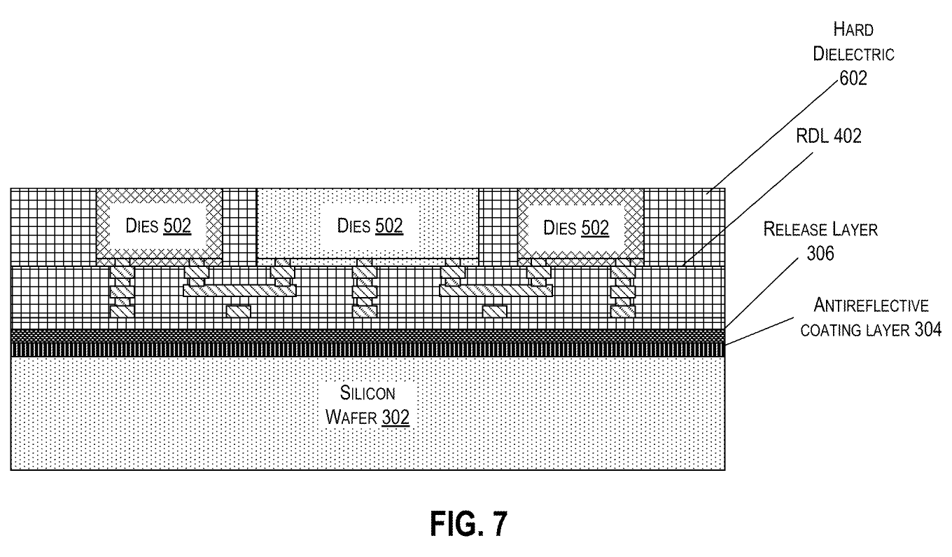

FIG. 6 illustrates a semiconductor device after the encapsulation of the dies, in accordance with some embodiments. In some embodiments, a thick hard dielectric 602 encapsulates the dies 502 .

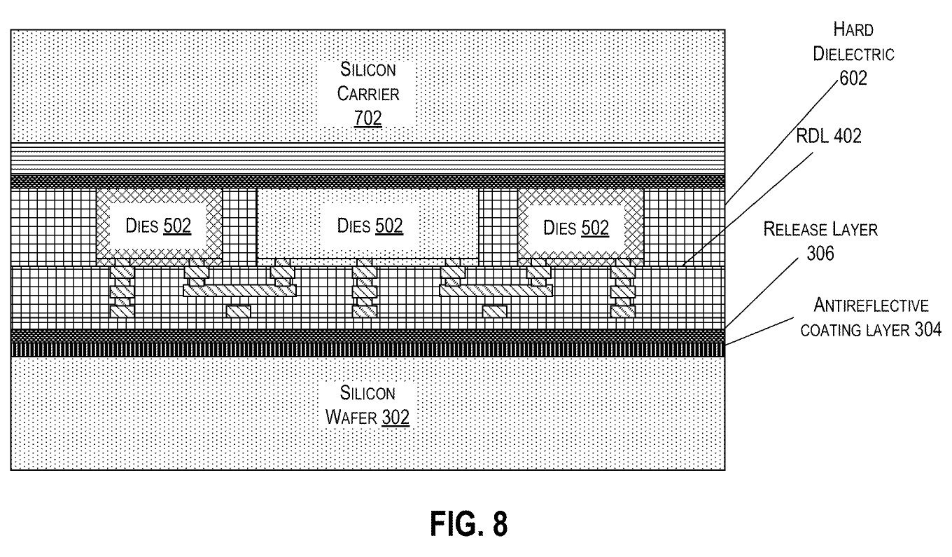

FIG. 7 illustrates a semiconductor device after the backside grinding, in accordance with some embodiments. In some embodiments, a grinding is performed over the backside of the semiconductor device followed by polishing the semiconductor dies and the encapsulating layer. In some embodiments, additional layers can be stacked with semiconductor dies, if needed.

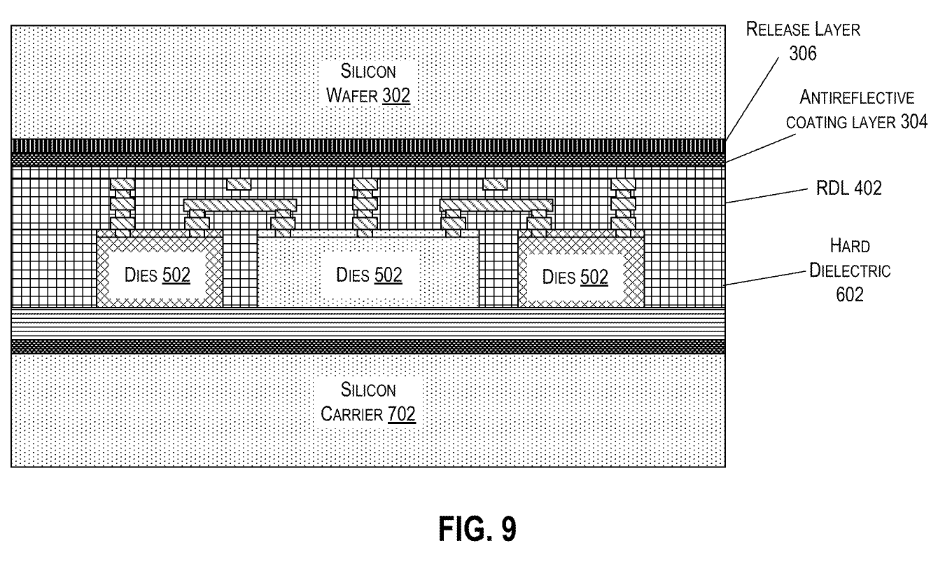

FIG. 8 illustrates a semiconductor device after the attachment of the second silicon wafer, in accordance with some embodiments. In some embodiments, a second silicon wafer, e.g., silicon carrier 702, is attached to the backside of the thinned semiconductor dies. This step can be achieved by wafer-to-wafer temporary bonding, such as adhesive bonding.

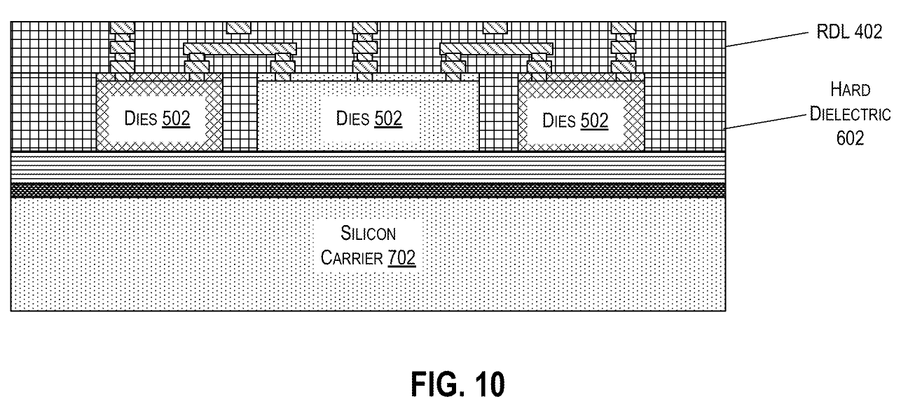

FIG. 9 illustrates a semiconductor device after the wafer is flipped, in accordance with some embodiments. In some embodiments, the semiconductor device is flipped.

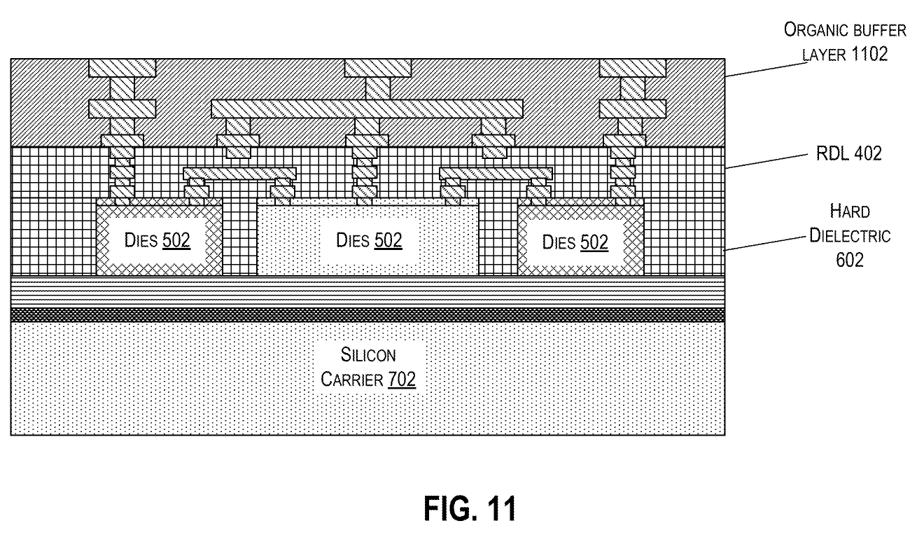

FIG. 10 illustrates a semiconductor device after the release of the first silicon wafer, in accordance with some embodiments. In some embodiments, the first silicon wafer is released by an IR laser release. A surface cleaning and polishing can be performed to expose the copper pads.

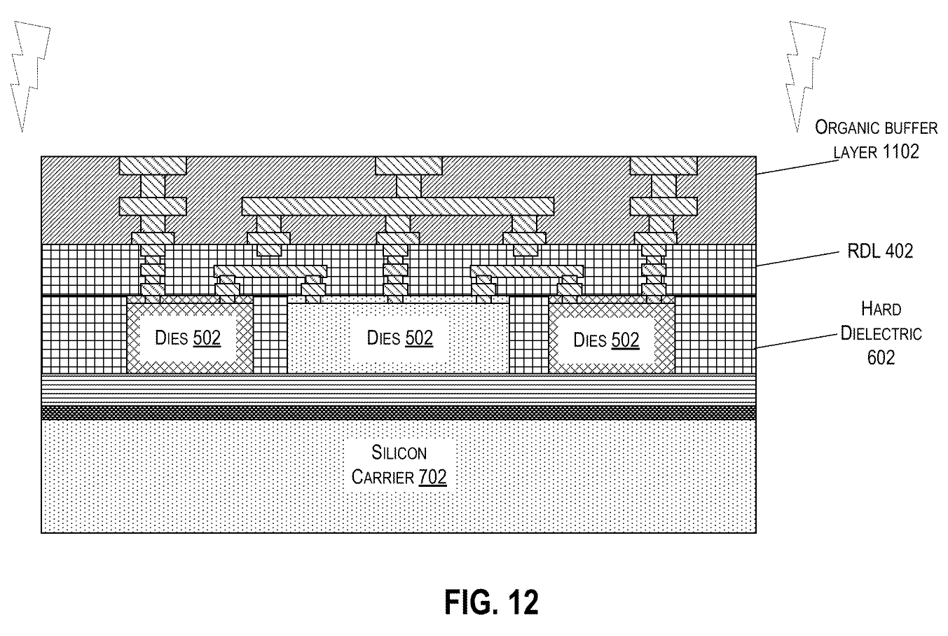

FIG. 11 illustrates a semiconductor device after the build-up organic buffer layer, in accordance with some embodiments. In some embodiments, the organic buffer layer 1102 is formed with interconnections with PI spin-coating, litho-patterning, and Cu Damascene processes.

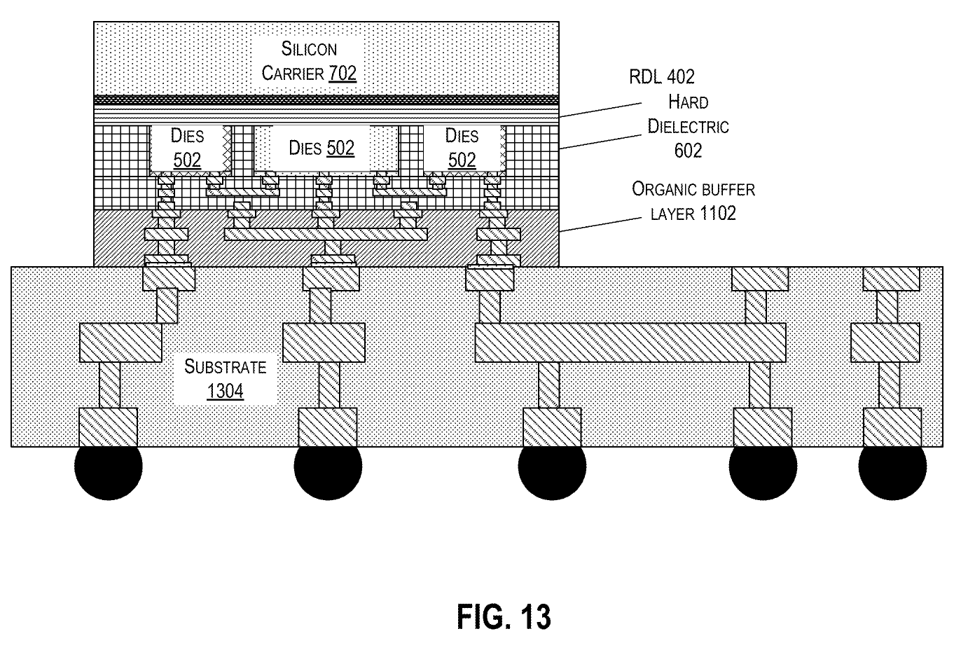

FIG. 12 illustrates a semiconductor device after the dicing the semiconductor device, in accordance with some embodiments. In some embodiments, the semiconductor device is diced into dies.

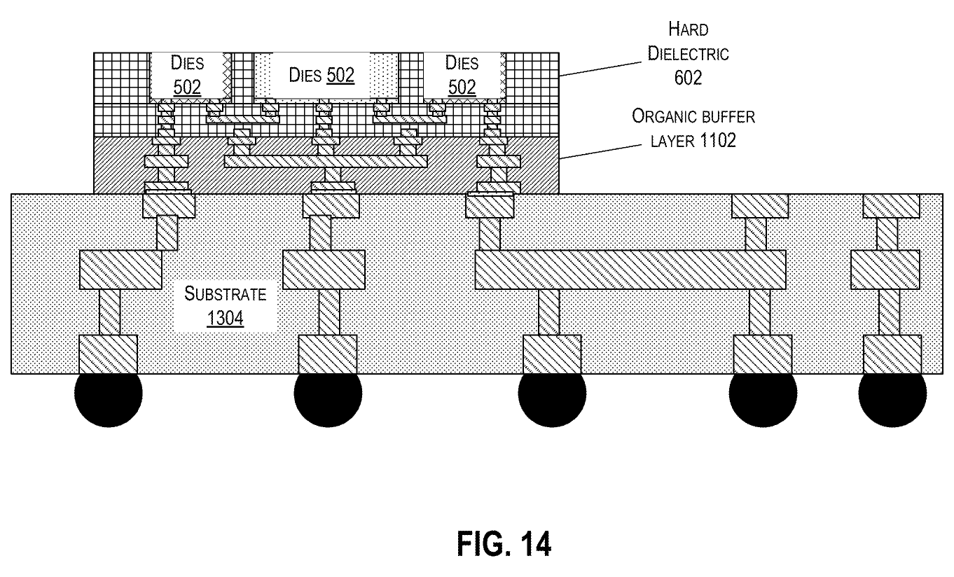

FIG. 13 illustrates a semiconductor device after the bonding the dies to the substrate, in accordance with some embodiments. In some embodiments, the dies 502 are bonded to the substrate 1304 . The substrate can be an organic substrate, a ceramic substrate or a glass substrate. In some embodiments, solder hybrid bonding can be performed.

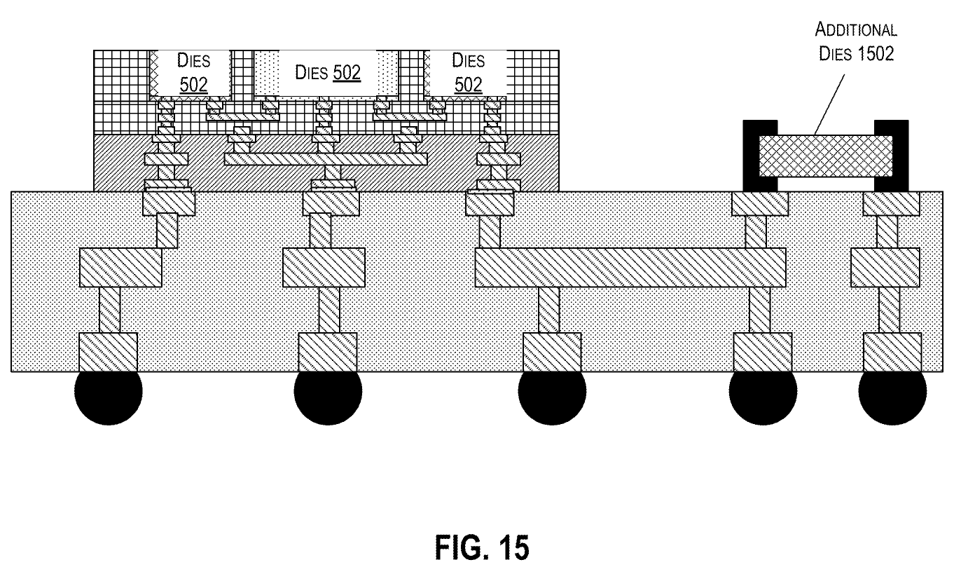

FIG. 14 illustrates a semiconductor device after the release of the second silicon wafer, in accordance with some embodiments. In some embodiments, the second silicon wafer is released.

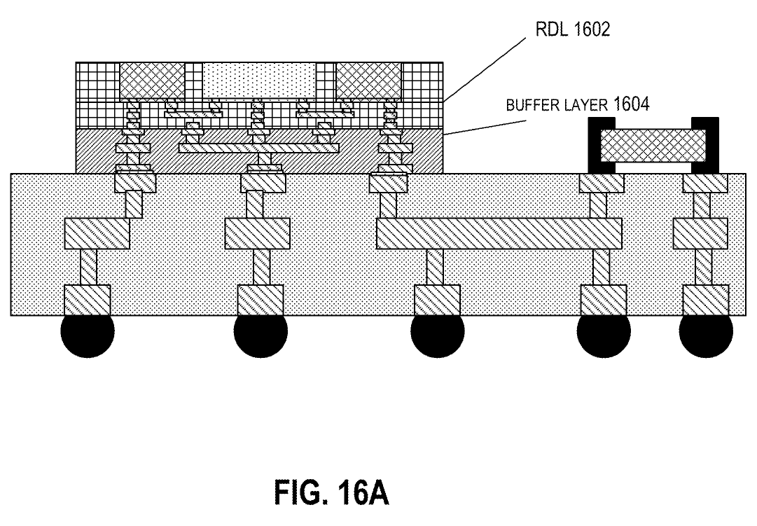

FIG. 15 illustrates a semiconductor device after the assembling of additional devices, in accordance with some embodiments. In some embodiments, additional devices 1502 , such as capacitor, are assembled on the substrate.

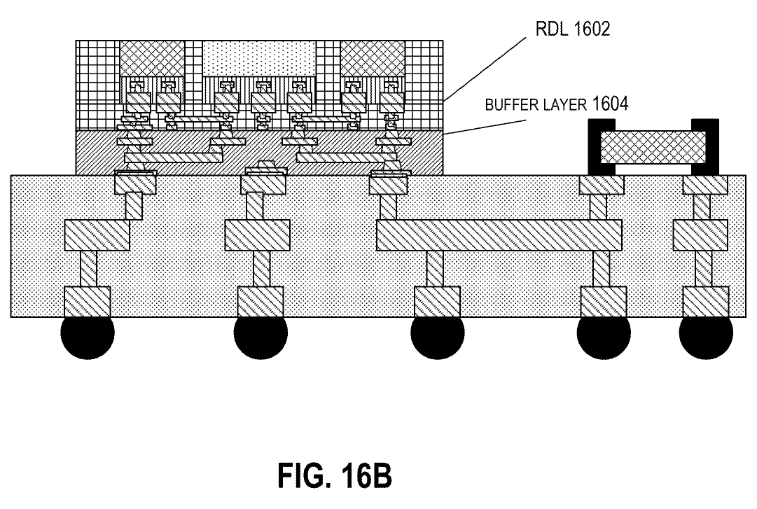

FIGS. 16A-16B illustrate a semiconductor device with different bonding, in accordance with some embodiments. FIG. 16A shows face-to-face bonding between the RDL 1602 and the buffer layer 1604 , while FIG. 16B shows back-to-back bonding between the RDL 1602 and the buffer layer 1604 .

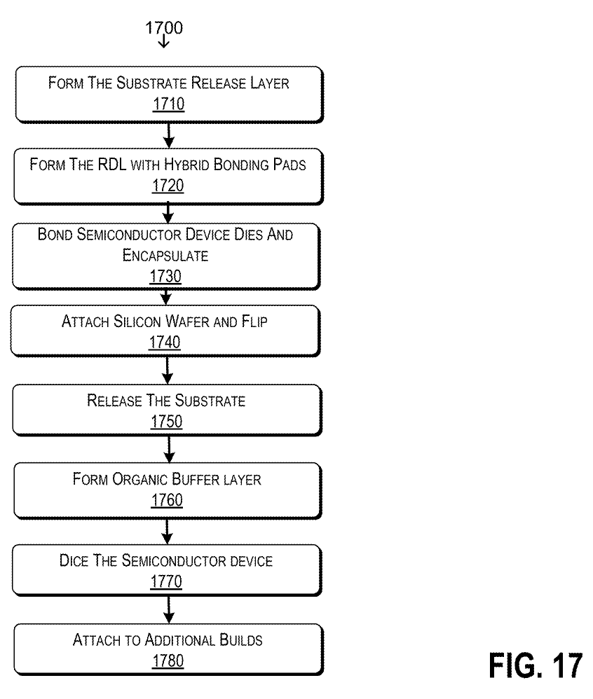

FIG. 17 illustrates a method 1700 for forming the semiconductor device, in accordance with some embodiments. As shown by block 1710 , a substrate and the release layer are formed.

As shown by block 1720 , the RDL with hybrid bonding pads are formed.

As shown by block 1730 , the semiconductor dies are bonded and encapsulated.

As shown by block 1740 , the silicon wafer is attached and the semiconductor device is flipped.

As shown by block 1750, the substrate is released.

As shown by block 1760, the organic buffer layer is formed.

As shown by block 1770, the semiconductor device is diced.

As shown by block 1780, additional builds are attached.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a substrate;
an organic buffer layer over the substrate;
a redistribution layer (RDL) over the organic buffer layer; and
one or more semiconductor dies over the RDL,
wherein the one or more semiconductor dies are face-to-face hybrid bonded to the RDL.

2. The semiconductor device of claim 1, wherein the one or more semiconductor dies are encapsulated.

3. The semiconductor device of claim 1, wherein the substrate comprises a plurality of interconnections and a plurality of pads.

4. The semiconductor device of claim 1, wherein the organic buffer layer comprises a plurality of interconnections and a plurality of pads.

5. The semiconductor device of claim 1, further comprising back-to-back connections between the RDL and the organic buffer layer.

6. The semiconductor device of claim 1, wherein the organic buffer layer is face-to-face joined to the substrate.

7. The semiconductor device of claim 1, wherein the RDL comprises:
a plurality of interconnections;
a plurality of pads; and
a dielectric layer.

8. The semiconductor device of claim 7, wherein the dielectric layer is made of at least one of: SiO2, SiN and SiCN.

9. The semiconductor device of claim 1, further comprising:
a logic device;
a passive device; and
one or more high bandwidth memory.

10. A method for fabrication of a semiconductor device, the method comprising:
forming a substrate;
forming an organic buffer layer over the substrate;
forming a redistribution layer (RDL) over the organic buffer layer;
forming one or more semiconductor dies over the RDL; and
bonding the one or more semiconductor dies to the RDL, wherein the bonding is a hybrid bonding.

11. The method of claim 10, further comprising:
encapsulating the one or more semiconductor dies.

12. The method of claim 10, wherein forming the substrate comprises:
forming a plurality of interconnections; and
forming a plurality of pads.

13. The method of claim 10, wherein forming the organic buffer layer comprises:
forming a plurality of interconnections; and
forming a plurality of pads.

14. The method of claim 10, further comprising:
forming back-to-back connections between the RDL and the organic buffer layer.

15. The method of claim 10, further comprising:
face-to-face joining the organic buffer layer to the substrate.

16. The method of claim 10, wherein forming the RDL comprises:
forming a plurality of interconnections;
forming a plurality of pads; and
forming a dielectric layer.

17. The method of claim 16, wherein the dielectric layer is made of at least one of: SiO2, SiN and SiCN.

18. The method of claim 10, further comprising:
forming a logic device;
forming a passive device; and
forming one or more high bandwidth memory.

19. A semiconductor device, comprising:
a buffer layer;
a redistribution layer (RDL) over the buffer layer; and
one or more semiconductor dies over the RDL, wherein each of the buffer layer and the RDL includes at least: one or more interconnects and one or more pads, and wherein the RDL and the buffer layer are connected via back-to-back connections.

20. The semiconductor device of claim 19, further comprising:
a substrate comprising one or more interconnections and one or more pads; and
one or more semiconductor dies over the RDL.
